(19) United States
(12) Patent Application Publication
(10) Pub. No.: US 2025/0164893 A1
(43) Pub. Date: May 22, 2025

(54) APPARATUS AND METHOD FOR PROVIDING SENSOR DATA OF AN OPTICAL SYSTEM, OPTICAL SYSTEM AND LITHOGRAPHY APPARATUS HAVING AN OPTICAL SYSTEM

(71) Applicant: Carl Zeiss SMT GmbH, Oberkochen (DE)

(72) Inventors: Steffen VAAS, Ellwangen (DE); Stefan KRONE, Ellwangen (DE); Thomas RETTENMAIER, Aalen-Dewangen (DE); Lars BERGER, Aalen-Unterkochen (DE)

(21) Appl. No.: 19/008,383

(22) Filed: Jan. 2, 2025

Related U.S. Application Data
(63) Continuation of application No. PCT/EP2023/069221, filed on Jul. 11, 2023.

(30) Foreign Application Priority Data
Jul. 11, 2022 (DE) 10 2022 207 027.5

(51) Int. Cl. G03F 7/00; H03H 17/02; H03M 1/12

(52) U.S. Cl. CPC G03F 7/70508; G03F 7/70208; G03F 7/70525; G03F 7/7085; H03H 17/02; H03M 1/12

(57) ABSTRACT

An apparatus provides sensor data from at least one sensor of an optical system of a lithography apparatus. The apparatus comprises an analogue-to-digital converter and a digital filter device connected downstream of the analogue-to-digital converter. The analogue-to-digital converter is configured to convert an analogue signal sequence, which is provided via a number N of channels and includes a number N of analogue sensor signals from the number N of sensors of the optical system, into a digital signal sequence including N digital sensor signals. The analogue-to-digital converter and the digital filter device have the same frequency-synchronized system clock. The digital filter device is configured to filter the N digital sensor signals of the digital signal sequence in a channel-specific manner for providing and storing a respective filtered digital sensor signal for each of the N channels.

### CROSS-REFERENCE TO RELATED APPLICATIONS

The present application is a continuation of, and claims benefit under 35 USC 120 to, international application No. PCT/EP2023/069221, filed Jul. 11, 2023, which claims benefit under 35 USC 119 of German Application No. 10 2022 207 027.5, filed Jul. 11, 2022. The entire disclosure of each of these applications is incorporated by reference herein.

### FIELD

The present disclosure relates to an apparatus for providing sensor data from sensors of an optical system of a lithography apparatus. The present disclosure further relates to an optical system having such an apparatus and to a lithography apparatus having such an optical system. The present disclosure additionally relates to a method for providing sensor data from sensors of an optical system of a lithography apparatus.

### BACKGROUND

Microlithography is used for production of microstructured component parts, for example integrated circuits. The microlithography process is performed with a lithography apparatus, which has an illumination system and a projection system. The image of a mask (reticle) illuminated via the illumination system is projected here via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range from 0.1 nanometer (nm) to 30 nm, for example 13.5 nm, are currently under development. Since most materials absorb light of this wavelength, it can be desirable in such EUV lithography apparatuses to use reflective optics, which is to say mirrors, instead of—as previously-refractive optics, which is to say lens elements.

An optical system of a lithography apparatus can have a vacuum housing. In the vacuum housing, various sensors, for example temperature measurement sensors, such as NTC sensors, photodiodes or capacitors, are arranged. These sensors can provide a respective analogue sensor signal on the output side. If a plurality of sensors are present, the analogue sensor signals of the plurality of sensors can be supplied to a multiplexer, which can provide an analogue signal sequence including the multiplexed analogue sensor signals from the sensors on the output side. Outside of the vacuum housing, an analogue filter can be coupled to the multiplexer, and an analogue-to-digital converter can be connected downstream of the analogue filter. The analogue-to-digital converter can convert the analogue signal sequence filtered by the analogue filter into a digital signal sequence and can supply it to a digital signal processing unit for further processing.

Since conventional filters generally involve a certain amount of settling time to switch between the different channels for the different signals from the different sensors before their regular function is established, conventional filter concepts can usually be used only with great limitations. This is because after every time a channel change takes place, it can be desirable to wait again for the settling time of the filter to finish, which can take multiple times the time period compared to the sampling process. Consequently, the sensor values can usually be sampled only with time limitations. However, if the filter is omitted due to these effects and a high sampling rate is used, undesirable aliasing effects could significantly interfere with the used signal. However, if the conventional filter is used, in general, only a greatly limited sampling rate can be used with constant multiplexing of the sensor signals due to the long filter settling time. The same is true regarding the sampling of an individual sensor signal with a precise but slowly sampling analogue-to-digital converter.

### SUMMARY

The present disclosure seeks to improve the provision of sensor data from sensors of an optical system of a lithography apparatus.

According to a first aspect, an apparatus for providing sensor data from a number N, with N≥1, of sensors of an optical system of a lithography apparatus is proposed, with the apparatus comprising:
an analogue-to-digital converter, which is configured to convert an analogue signal sequence, which is provided via a number N of channels and includes a number N of analogue sensor signals from the number N of sensors of the optical system, into a digital signal sequence including N digital sensor signals, and
a digital filter device connected downstream of the analogue-to-digital converter, wherein the analogue-to-digital converter and the digital filter device have the same frequency-synchronized system clock and the digital filter device is configured to filter the N digital sensor signals of the digital signal sequence in a channel-specific manner for providing and storing a respective filtered digital sensor signal for each of the N channels.

The present apparatus can dispense with an analogue filter in order to circumvent the limitation of the maximum sampling rate due to the settling process of the analogue filter.

The digital filter device used here, which can internally buffer the filter values of different channels, i.e. the filtered digital sensor signals for the N channels, can help enable multiplexing of the channel to be measured (also known as sensor channel) synchronously with the respective filter values. It is possible in this way to circumvent the desire for the digital filter to settle again with each channel change.

According to one embodiment, the sampling frequency of the analogue-to-digital converter and the properties of the digital filter device are matched to one another such that interference frequency bands are suppressed. This approach can be used both in the case of one and also in the case of multiple interference frequency bands. The sampling frequency of the analogue-to-digital converter can be selected here for example such that known interference frequencies are suppressed.

The digital filter device comprises one or more digital filters. Examples in this respect will be mentioned below. The used bandwidth of the respective digital sensor signal is not influenced, or not substantially influenced, during filtering.

According to one embodiment, the filtering of undersampled interference frequencies is also possible.

According to one embodiment, the apparatus comprises a control unit, which is configured to clock-synchronously control the analogue-to-digital converter and the digital filter device via the frequency-synchronized system clock.

Controlling clock-synchronously in the present case means in particular controlling via the frequency-synchronized system clock. The system clock can be a frequency-synchronized and phase-synchronized system clock.

The control unit can provide in this case a precisely timed trigger. For example, the control unit is embodied in the form of a state machine, for example in the form of a finite-state machine. The state machine can help enable cycle-accurate control for switching the multiplexer unit, the start of the quantization by way of the analogue-to-digital converter and the correct switching of the filter values of the associated channel of the digital filter device. This can help ensure that during the periodic actuation of the individual components no time-of-flight deviations could occur in the form of jitter, which could have the effect of phase noise in the spectral representation of the respective sampled signal.

According to one embodiment, the analogue-to-digital converter is the unit that provides the frequency-synchronized system clock. The digital filter device and the control unit are then controlled via this provided frequency-synchronized system clock.

According to an embodiment, the apparatus comprises a multiplexer unit, which is configured to receive a plurality N, with N≥2, of analogue sensor signals from a plurality N of sensors of the optical system via a plurality N of channels and to provide on the output side an analogue signal sequence including N multiplexed analogue sensor signals to the analogue-to-digital converter.

According to one embodiment, the control unit is configured to clock-synchronously control the analogue-to-digital converter, the digital filter device and the multiplexer unit via the frequency-synchronized system clock.

According to an embodiment, the apparatus comprises:
a multiplexer unit, which is configured to receive a plurality N of analogue sensor signals from a plurality N of sensors of the optical system via a plurality N of channels and to provide on the output side an analogue signal sequence including the N multiplexed analogue sensor signals, with N≥2,
the analogue-to-digital converter, which is connected to the multiplexer unit and is configured to convert the analogue signal sequence provided by the multiplexer unit into a digital signal sequence including N multiplexed digital sensor signals, and
the digital filter device, which is connected downstream of the analogue-to-digital converter and is configured to filter the multiplexed digital sensor signals of the digital signal sequence in a channel-specific manner for providing and storing a respective filtered digital sensor signal for each of the N channels.

The multiplexer unit may also be referred to as multiplexer. The analogue-to-digital converter can also be referred to as ADC.

For example, a storage unit with N memory locations, which is connected downstream of the digital filter device, is provided. Here, each of the N memory locations is assigned exactly one of the N channels. The respective memory location is configured for storing the respective filtered digital sensor signal for the respective one of the N channels. In addition, a control unit can be provided. The control unit can serve for centrally controlling and computing the digital filter device. It may be a digital circuit, for example an FPGA or an ASIC or a microprocessor.

In order to operate the multiplexing of a plurality of different sensor channels in such a way that no new settling of the filter is desirable upon each channel change, the disclosure makes provision for the filter values of the different channels to be buffered. This can be accomplished for example by way of multiple instantiation of the digital filter. Details in this respect will be mentioned below.

The optical system can be a projection optical unit of the lithography apparatus or projection exposure apparatus. However, the optical system may also be an illumination system. The projection exposure apparatus may be an EUV lithography apparatus. EUV stands for “extreme ultraviolet” and denotes a wavelength of the working light of between 0.1 nm and 30 nm. The projection exposure apparatus may also be a DUV lithography apparatus. DUV stands for “deep ultraviolet” and denotes a wavelength of the working light of between 30 nm and 250 nm.

According to one embodiment, the multiplexer unit is embodied in the form of an N×1 multiplexer unit. The N×1 multiplexer unit is configured to receive the N analogue sensor signals from the N sensors of the optical system via the N channels and to provide the analogue signal sequence including the N multiplexed analogue sensor signals on the output side. Generally, N≥2. For example, N can be greater than 100 or greater than 1000.

According to an embodiment, the digital filter device comprises:
a plurality N of parallel digital filters, wherein each of the N digital filters is assigned exactly one of the N channels, and
a demultiplexer unit, which is connected between the analogue-to-digital converter and the N digital filters and is configured to demultiplex the multiplexed digital sensor signals of the digital signal sequence in a channel-specific manner for the N channels to the N digital filters.

This embodiment utilizes the multiple instantiation, already mentioned above, of the digital filter, in the present case an N-fold instantiation of the digital filter. The respective digital filter comprises in particular a memory location for buffering the respective filter value. In addition, a plurality of filter values per channel can be buffered. A buffer can be used for this purpose. The digital filter device is thus suitable for parallel processing of a plurality of channels as universal computing unit.

According to an embodiment, the apparatus comprises a storage unit with N memory locations, which is connected downstream of the N digital filters. Here, each of the N memory locations is assigned exactly one of the N channels. The respective memory location is configured for storing the respective filtered digital sensor signal for the respective channel of the N channels.

According to an embodiment, the apparatus comprises a digital-to-analogue converter connected between the control unit and the N sensors. The control unit is configured here to clock-synchronously control the multiplexer unit, the analogue-to-digital converter, the digital filter device, the storage unit and the N sensors via the digital-to-analogue converter.

Owing to the additional use of the digital-to-analogue converter, it is possible for the control unit to also be able to control the N sensors clock-synchronously with the further components of the system.

According to an embodiment, the digital filter device comprises a plurality M of series-connected delay units for receiving the digital signal sequence including the digital sensor signals, with M≥2. The respective delay unit has here in each case one memory location for each of the N channels. Each of the N memory locations is assigned exactly one of the N channels. The delay units are configured to shift in a channel-specific manner for the N channels the memory contents of their memory locations in accordance with the system clock into the memory locations of the delay unit that is respectively connected downstream.

This embodiment can allow that hardware resources in the form of memories and computing power can be saved. The present digital filter device with the plurality of delay units is configured here to multiplex between the filter values of the different channels and to provide the respectively selected channel on the output side.

According to an embodiment, a respective multiplier unit is connected downstream of each of the M delay units. Each multiplier unit is assigned here a specific filter coefficient. The delay units are configured to supply the memory contents of a specific channel of the N channels to the M multiplier units in accordance with the system clock. The M multiplier units are configured to multiply the memory contents supplied by the M delay units by the specific filter coefficients. An adding unit connected downstream of the M multiplier units is configured to add up the products of the multiplications provided by the M multiplier units for providing the filtered digital sensor signal of the specific channel.

According to an embodiment, the digital filter device forms an FIR filter, an IIR filter, a biquad filter or a CIC filter.

The multiplier units thus process always exactly one specific channel at a specific time and are thus configured to provide the filtered digital sensor signal of the specific channel on the output side using the adding unit.

According to an embodiment, the apparatus comprises a storage unit with N memory locations, which is connected downstream of the adding unit. Each of the N memory locations is assigned exactly one of the N channels. The respective memory location is configured here for storing the respective filtered digital sensor signal for the respective one of the N channels.

According to an embodiment, the apparatus comprises a control unit, which is configured to clock-synchronously control the multiplexer unit, the analogue-to-digital converter, the delay units and the storage unit via the frequency-synchronized system clock.

According to an embodiment, the apparatus comprises a digital-to-analogue converter connected between the control unit and the N sensors. The control unit is configured to clock-synchronously control the multiplexer unit, the analogue-to-digital converter, the delay units, the storage unit and the N sensors via the digital-to-analogue converter via the frequency-synchronized system clock.

By using the digital-to-analogue converter, current and/or voltage values up to the sensors can be controlled in a targeted manner in order to bring about resonances, for example. Owing to the use of the digital-to-analogue converter, it is furthermore possible to exert influence on the sensor behaviour of the N sensors using further electronically controllable circuits, such as trimmable resistors, capacitors, coils or heating wires.

According to an embodiment, the digital filter device, the storage unit and the control unit are provided, in particular integrated, in one processor device. The processor device is in particular a microprocessor, a digital signal processor (DSP) or an FPGA (field programmable gate array).

For example, if the processor device controls an electric motor in which the rotational speed is actively stipulated, it is possible, for example on the basis of a model, to predict the induced interference signals in dependence on the rotational speed. It is thus possible with the dynamic control of the rotational speed of the motor to also continuously adapt the filtering of the sensor values through the digital filter device.

The embodiment as a processor device or as a digital circuit, such as FPGA, ASIC or digital logic module, enables cycle-accurate conversion, as a result of which phase noise can be reduced further.

According to an embodiment, the processor device furthermore comprises a signal analysis unit. The signal analysis unit is configured to analyse the digital sensor signals of the digital signal sequence and/or the filtered digital sensor signals and to adapt in dependence thereon at least one property of the digital filter device, in particular the filter coefficients of the digital filter device, and/or the sampling frequency of the analogue-to-digital converter.

Owing to the analysis of the digital signal sequence and/or of the filtered digital signal sequence, the signal analysis unit is suitable for adaptive noise suppression. The signal analysis unit here in particular offers the possibility to adapt the noise suppression during operation, for example by continuously analysing the input signal or the transfer function of the input signal and output signal. The adaptive noise suppression can in particular be achieved either by changing the sampling frequency of the analogue-to-digital converter or by adapting the digital filter device. Depending on the implementation, it is possible here, in addition to the filter coefficients, to also adapt the structure of the digital filter device.

According to an embodiment, the N sensors and the multiplexer unit are arranged in a vacuum housing of the optical system. The analogue-to-digital converter and the digital filter device are in this case arranged in particular outside the vacuum housing.

According to an embodiment, the N sensors are arranged in a vacuum housing of the optical system and the multiplexer unit is arranged outside the vacuum housing.

According to an embodiment, the sampling frequency of the analogue-to-digital converter is selected such that the sampling frequency is smaller for filtering the interference frequency than that of twice the interference frequency. As a result, it is also possible to suppress high-frequency interferences with the analogue-to-digital converter which are trimmed for high accuracy rather than speed.

The respective unit, for example the control unit, can be implemented by way of hardware technology and/or also software technology. In the case of a hardware implementation, the unit can be in the form of an apparatus or part of an apparatus, for example a computer or a microprocessor or part of the control apparatus. In the case of a software implementation, the unit can be in the form of a computer program product, a function, a routine, part of a program code or an executable object.

According to a second aspect, an optical system for a lithography apparatus is proposed, wherein the optical system comprises an apparatus according to the first aspect or according to one of the embodiments of the first aspect.

According to an embodiment, the optical system is in the form of an illumination optical unit or in the form of a projection optical unit of a lithography apparatus.

According to a third aspect, a lithography apparatus is proposed, which has an optical system in accordance with the second aspect or in accordance with one of the embodiments of the second aspect.

According to a fourth aspect, a method for providing sensor data from a number N, with N≥1, of sensors of an optical system of a lithography apparatus is proposed. The method comprises the steps of:
converting an analogue signal sequence, which is provided via a number N of channels and includes a number N of analogue sensor signals from the number N of sensors of the optical system, into a digital signal sequence including N digital sensor signals, and
filtering the N digital sensor signals of the digital signal sequence in a channel-specific manner for providing and storing a respective filtered digital sensor signal for each of the N channels via a digital filter device connected downstream of the analogue-to-digital converter, wherein the analogue-to-digital converter and the digital filter device have the same frequency-synchronized system clock.

According to one embodiment, the method comprises the steps of:
receiving a plurality N, with N≥2, of analogue sensor signals from a plurality N of sensors of the optical system via a plurality N of channels at a multiplexer unit,
providing an analogue signal sequence including the N multiplexed analogue sensor signals via the multiplexer unit,
transmitting the analogue signal sequence to an analogue-to-digital converter connected to the multiplexer unit,
converting the analogue signal sequence into a digital signal sequence including N multiplexed digital sensor signals via the analogue-to-digital converter, and
filtering the multiplexed digital sensor signals of the digital signal sequence in a channel-specific manner for providing and storing a respective filtered digital sensor signal for each of the N channels via a digital filter device connected downstream of the analogue-to-digital converter.

The embodiments described for the proposed apparatus apply correspondingly to the proposed method, and vice versa. Furthermore, the definitions and explanations in relation to the apparatus also apply correspondingly to the proposed method.

According to a fifth aspect, a design method for designing an apparatus comprising an analogue-to-digital converter for converting analogue sensor signals into digital sensor signals and a digital filter device, connected downstream of the analogue-to-digital converter, for filtering the digital sensor signals which include a used signal component with used signal frequencies of a used signal bandwidth and an interference signal component with at least one known interference frequency that is undersampled by the analogue-to-digital converter is proposed. The design method comprises:
selecting the sampling frequency of the analogue-to-digital converter in such a way that the at least one alias frequency of the undersampled interference signal components lies outside the used signal bandwidth and the sampling frequency is not a submultiple of the interference frequency, and
selecting the sampling frequency of the analogue-to-digital converter and the filter order of the digital filter device with low-pass behaviour in such a way that the digital filter device allows the signal components within the used signal bandwidth to pass and suppresses the at least one aliasing frequency of the undersampled interference signal components.

For the example of a moving average filter as digital filter device, the sampling frequency of the analogue-to-digital converter and the filter order can be selected such that the quotient of the sampling frequency and the filter order corresponds to a submultiple of the alias frequency and is greater than the used signal bandwidth.

The present design method is used for example for undersampled interference frequencies. The interference frequency or the interference frequencies and the alias frequency or alias frequencies are determined and therefore known a priori. The present design method accordingly is used in particular when the sampling rate of the analogue-to-digital converter is too low to be able to sample a specific interference frequency according to the Nyquist-Shannon sampling theorem, in particular either due to a very precise but slow analogue-to-digital converter and/or due to multiplexing of a plurality of signals from multiple channels that are to be processed in parallel. In the case of such undersampling of the interference frequency, aliasing effects occur, as a result of which the interference frequency occurs mirrored in a low frequency band. This is referred to as mirrored interference frequency or alias frequency.

According to the present design method, the sampling frequency of the analogue-to-digital converter and the filter order of the digital filter device are selected such that the following three conditions I, II and III are met:

### Condition I:

The sampling frequency of the analogue-to-digital converter is selected such that the at least one alias frequency lies outside the used signal bandwidth of the digital sensor signals. In addition, the sampling frequency of the analogue-to-digital converter is selected such that it is greater than twice the used signal bandwidth.

### Condition II:

The sampling frequency of the analogue-to-digital converter is selected such that the sampling frequency is not a submultiple of the interference frequency.

### Condition III:

The digital filter arrangement has a low-pass behaviour which allows signal components within the used signal bandwidth to pass and suppresses the aliasing frequencies of the undersampled interference signal components.

For the example of the moving average filter as digital filter device, the condition III can be formulated using the conditions IIIa and IIIb:

### Condition IIIa:

The sampling frequency of the analogue-to-digital converter and the filter order of the digital filter device are selected such that the quotient of the sampling frequency and the filter order corresponds to a submultiple of the alias frequency.

### Condition IIIb:

The sampling frequency of the analogue-to-digital converter and the filter order of the digital filter device are selected such that the quotient of the sampling frequency and the filter order is greater than the used signal bandwidth.

The filter order of the digital filter device corresponds in particular to the plurality M of series-connected delay units of the digital filter device.

The apparatus designed using the present design method, which apparatus comprises an analogue-to-digital converter and a digital filter device, is capable of filtering the alias frequencies of the undersampled known interference frequencies without significantly influencing the used signal bandwidth of the used signal.

The alias frequency can also be referred to as mirrored interference frequency or as mirror frequency.

The apparatus designed using the present design method is configured for providing sensor data from a number N, with N≥1, of sensors of an optical system of a lithography apparatus and can comprise:
an analogue-to-digital converter, which is configured to convert an analogue signal sequence, which is provided via a number N of channels and includes a number N of analogue sensor signals from the number N of sensors of the optical system, into a digital signal sequence including N digital sensor signals, and
a digital filter device connected downstream of the analogue-to-digital converter, wherein the analogue-to-digital converter and the digital filter device have the same frequency-synchronized system clock and the digital filter device is configured to filter the N digital sensor signals of the digital signal sequence in a channel-specific manner for providing and storing a respective filtered digital sensor signal for each of the N channels,
wherein the digital filter device comprises a plurality M of series-connected delay units for receiving the digital signal sequence including the digital sensor signals, with M≥2, wherein the respective delay unit has in each case one memory location for each of the N channels, wherein each of the N memory locations is assigned exactly one of the N channels, wherein the delay units are configured to shift in a channel-specific manner for the N channels the memory contents of their memory locations in accordance with the system clock into the memory locations of the delay unit that is respectively connected downstream.

According to one embodiment of the design method, the digital filter device is in the form of a notch filter.

According to an embodiment of the design method, the digital filter device is in the form of a moving average filter in an FIR filter structure.

The following example of a moving average filter shows an exemplary use of the above-described design method:

Based on the above conditions I to III (IIIa, IIIb), the filter order M of the digital filter device is selected at a sampling frequency fₛ of 100 Hz, a used signal bandwidth f_{N} of 2 Hz, an interference frequency f_{d} of 60 Hz and an alias frequency fₐ at 40 Hz as follows:
1. A submultiple of the alias frequency fₐ (mirrored interference frequency) of 40 Hz is 10.
2. For the divisor 10: f_{S}/M=10→M=10. The divisor 10 and the resulting filter order M=10 meet all the conditions I to III, and also IIIa and IIIb. Consequently, the filter order M=10 is admissible for the present example.

According to a further embodiment, a plurality of digital filter devices are series-connected for improving the signal-to-noise ratio of the filtered digital sensor signals.

A plurality of digital filter devices, in particular in the form of a respective FIR filter unit, can be connected in series and/or combined with low-pass filters, high-pass filters and/or bandpass filters.

According to a sixth aspect, an apparatus comprising an analogue-to-digital converter for converting analogue sensor signals into digital sensor signals and a digital filter device, connected downstream of the analogue-to-digital converter, with low-pass behaviour for filtering the digital sensor signals which include a used signal component with used signal frequencies of a used signal bandwidth and an interference signal component with at least one determinable alias frequency of a known interference frequency undersampled by the analogue-to-digital converter in the analogue sensor signal is proposed, wherein the sampling frequency of the analogue-to-digital converter and the filter order of the digital filter device are selected such that the at least one alias frequency lies outside the used signal bandwidth and the sampling frequency is not a submultiple of the interference frequency and such that the digital filter device allows the signal components within the used signal bandwidth to pass and suppresses the at least one alias frequency of the undersampled interference signal components.

According to a seventh aspect, a method for operating an apparatus as explained above is proposed, wherein the analogue-to-digital converter and the digital filter device are controlled such that the analogue-to-digital converter converts from each of the N channels in turn a successive series of sensor signal values of the analogue sensor signals into digital sensor signals and the digital filter device subsequently filters them.

The apparatus used in accordance with the seventh aspect can be configured for providing sensor data from a number N, with N≥1, of sensors of an optical system of a lithography apparatus and can comprise:
an analogue-to-digital converter, which is configured to convert an analogue signal sequence, which is provided via a number N of channels and includes a number N of analogue sensor signals from the number N of sensors of the optical system, into a digital signal sequence including N digital sensor signals, and
a digital filter device connected downstream of the analogue-to-digital converter, wherein the analogue-to-digital converter and the digital filter device have the same frequency-synchronized system clock and the digital filter device is configured to filter the N digital sensor signals of the digital signal sequence in a channel-specific manner for providing and storing a respective filtered digital sensor signal for each of the N channels,
wherein the digital filter device comprises:
a plurality N of parallel digital filters, wherein each of the N digital filters is assigned exactly one of the N channels, and
a demultiplexer unit, which is connected between the analogue-to-digital converter and the N digital filters and is configured to demultiplex the multiplexed digital sensor signals of the digital signal sequence in a channel-specific manner for the N channels to the N digital filters.

According to one embodiment, the apparatus comprises a storage unit with N memory locations, which is connected downstream of the N digital filters. Here, each of the N memory locations is assigned exactly one of the N channels. The respective memory location is configured for storing the respective filtered digital sensor signal for the respective channel of the N channels.

According to one embodiment, the digital filter device averages the raw values of the digital sensor signals of the respective channel over the time period of an integer known period of the interference signal component for providing the filtered digital sensor signals.

In this way, the alias frequencies of the interference frequencies occurring due to the undersampling are filtered out.

“A” or “an” in the present case should not necessarily be understood to be restrictive to exactly one element. Rather, a plurality of elements, for example two, three or more, can also be provided. Nor should any other numeral used here be understood to the effect that there is a restriction to exactly the stated number of elements. Instead, unless indicated otherwise, numerical deviations upwards and downwards are possible.

Further possible implementations of the disclosure also include combinations, not mentioned explicitly, of features or embodiments described above or hereinafter with respect to the exemplary embodiments. In this case, a person skilled in the art will also add individual aspects as improvements or supplementations to the respective basic form of the disclosure.

Further features, configurations and aspects of the disclosure are the subject of the dependent claims and also of the exemplary embodiments of the disclosure that will be described hereinafter.

### BRIEF DESCRIPTION OF THE DRAWINGS

The disclosure will be explained in detail hereinafter on the basis of embodiments with reference to the appended figures.

FIG. 1 shows a schematic meridional section of a projection exposure apparatus for EUV projection lithography;

FIG. 2 shows a schematic illustration of a first embodiment of an apparatus for providing sensor data from sensors of an optical system of a lithography apparatus;

FIG. 3 shows a schematic illustration of a second embodiment of an apparatus for providing sensor data from sensors of an optical system of a lithography apparatus;

FIG. 4 shows a schematic illustration of a third embodiment of an apparatus for providing sensor data from sensors of an optical system of a lithography apparatus;

FIG. 5 shows a schematic illustration of a fourth embodiment of an apparatus for providing sensor data from sensors of an optical system of a lithography apparatus;

FIG. 6 shows a schematic illustration of a fifth embodiment of an apparatus for providing sensor data from sensors of an optical system of a lithography apparatus;

FIG. 7 shows a schematic illustration of a sixth embodiment of an apparatus for providing sensor data from sensors of an optical system of a lithography apparatus; and

FIG. 8 shows a schematic view of an embodiment of a method for providing sensor data from sensors of an optical system of a lithography apparatus;

FIG. 9 shows a schematic view of a further embodiment of a method for providing sensor data from sensors of an optical system of a lithography apparatus;

FIG. 10 shows a schematic view of an embodiment of a design method for designing an apparatus for providing sensor data from sensors of an optical system of a lithography apparatus;

FIG. 11 shows a schematic diagram for illustrating, by way of example, the sampling frequency, interference frequency, alias frequency and the frequency profile of an apparatus designed in accordance with FIG. 10; and

FIG. 12 shows a schematic view of an embodiment of a method for operating an apparatus for providing sensor data from sensors of an optical system of a lithography apparatus.

### DETAILED DESCRIPTION

Unless indicated otherwise, elements that are identical or functionally identical have been provided with the same reference signs in the figures. It should also be noted that the illustrations in the figures are not necessarily true to scale.

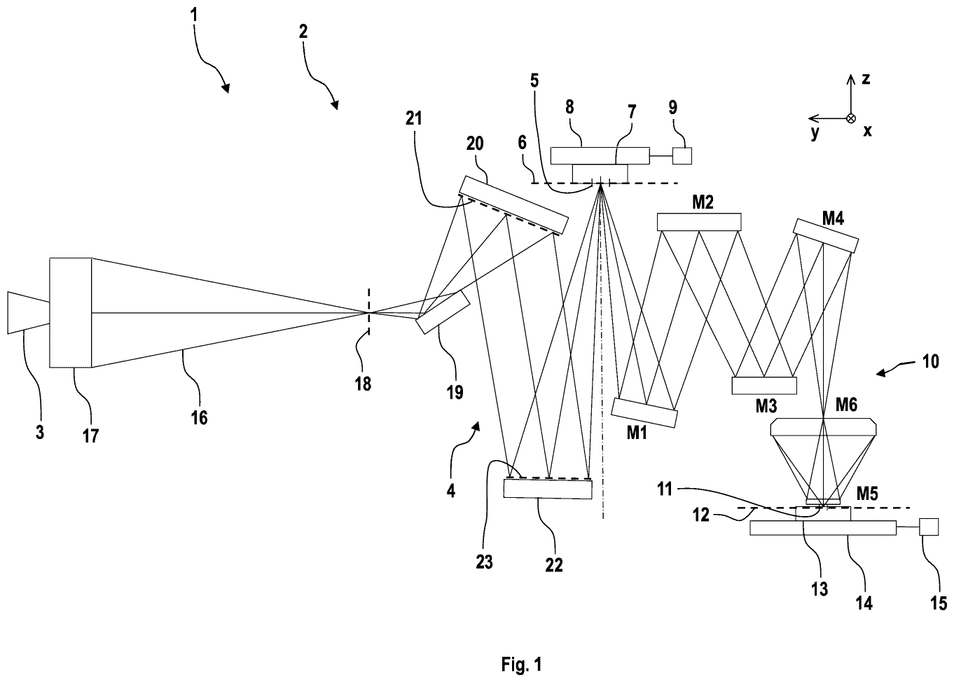

FIG. 1 shows an embodiment of a projection exposure apparatus 1 (lithography apparatus), in particular an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction y. The displacement, firstly, of the reticle 7 by way of the reticle displacement drive 9 and, secondly, of the wafer 13 by way of the wafer displacement drive 15 can be implemented so as to be mutually synchronized.

The light source 3 is an EUV radiation source. The light source 3 emits in particular EUV radiation 16, which is also referred to below as used radiation, illumination radiation or illumination light. In particular, the used radiation 16 has a wavelength in the range between 5 nm and 30 nm. The light source 3 may be a plasma source, for example an LPP (short for: laser produced plasma) source or a DPP (short for: gas-discharge produced plasma) source. It may also be a synchrotron-based radiation source. The light source 3 may be an FEL (short for: free-electron laser).

The illumination radiation 16 emerging from the light source 3 is focused by a collector 17. The collector 17 can be a collector with one or more ellipsoidal and/or hyperboloidal reflection surfaces. The at least one reflection surface of the collector 17 may be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. As an alternative or in addition, the deflection mirror 19 may be in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, in particular as rectangular facets or as facets with an arcuate edge contour or an edge contour of part of a circle. The first facets 21 may be in the form of plane facets or alternatively as facets with convex or concave curvature.

As is known for example from DE 10 2008 009 600 A1, the first facets 21 themselves can also each be composed of a multiplicity of individual mirrors, in particular a multiplicity of micromirrors. The first facet mirror 20 may in particular be in the form of a microelectromechanical system (MEMS system). For details, reference is made to DE 10 2008 009 600 A1.

Between the collector 17 and the deflection mirror 19, the illumination radiation 16 travels horizontally, which is to say in the y-direction y.

In the beam path of the illumination optical unit 4, a second facet mirror 22 is arranged downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 may have plane reflection surfaces or alternatively reflection surfaces with a convex or concave curvature.

The illumination optical unit 4 consequently forms a double-faceted system. This fundamental principle is also referred to as a fly's eye condenser (or integrator).

It can be desirable to arrange the second facet mirror 22 not exactly in a plane that is optically conjugate to a pupil plane of the projection optical unit 10. In particular, the second facet mirror 22 may be arranged so as to be tilted in relation to a pupil plane of the projection optical unit 10, as is described for example in DE 10 2017 220 586 A1.

With the aid of the second facet mirror 22, the individual first facets 21 are imaged into the object field 5. The second facet mirror 22 is the last beam-shaping mirror or indeed the last mirror for the illumination radiation 16 in the beam path upstream of the object field 5.

In a further embodiment (not illustrated) of the illumination optical unit 4, a transfer optical unit can be arranged in the beam path between the second facet mirror 22 and the object field 5, with the transfer optical unit contributing in particular to the imaging of the first facets 21 into the object field 5. The transfer optical unit can comprise exactly one mirror, but alternatively also two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are similarly possible. The projection optical unit 10 is a twice-obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, in particular with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may in particular have an anamorphic form. It has in particular different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, which is to say in a direction perpendicular to the scanning direction.

The projection optical unit 10 leads to a reduction in size of 8:1 in the y-direction y, which is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may in particular produce illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is in particular as homogeneous as possible. It can have a uniformity error of less than 2%. The field uniformity can be achieved by overlaying different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, in particular the subset of the second facets 23, which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described below.

The projection optical unit 10 may in particular have a homocentric entrance pupil. The latter can be accessible. It can also be inaccessible.

The entrance pupil of the projection optical unit 10 frequently cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find a surface area in which the spacing of the aperture rays, determined in pairwise fashion, is minimal. This surface area represents the entrance pupil or an area in real space that is conjugate thereto. In particular, this surface area has a finite curvature.

The projection optical unit 10 might have different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted with respect to an arrangement plane defined by the deflection mirror 19. The first facet mirror 20 is arranged tilted with respect to an arrangement plane defined by the second facet mirror 22.

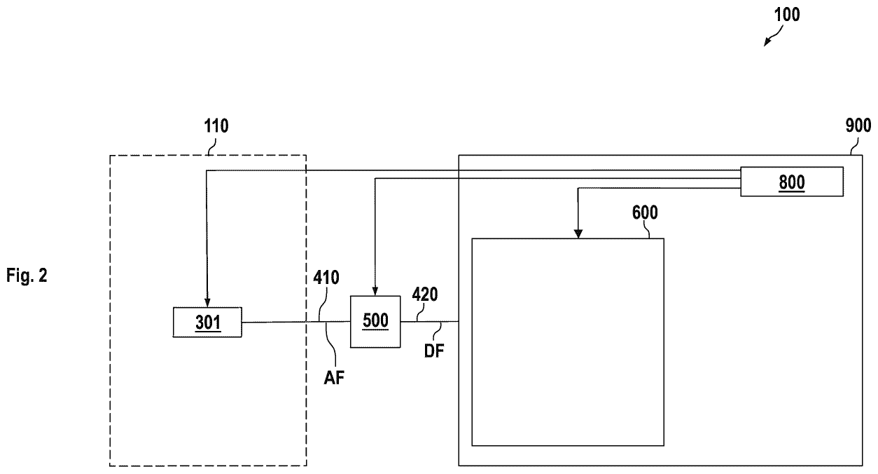

FIG. 2 shows a schematic illustration of a first embodiment of an apparatus 100. The apparatus 100 is arranged in an optical system 4, 10 of the lithography apparatus 1, for example the illumination optical unit 4 or the projection optical unit 10, and serves to provide sensor data from a number N, with N≥1, of sensors 301 of the optical system 4, of the lithography apparatus 1. Without impairing the generality, N=1 in FIG. 2. The sensor 301 is arranged in a vacuum housing 110 of the lithography apparatus 1.

The apparatus 100 in FIG. 2 comprises an analogue-to-digital converter 500. The analogue-to-digital converter 500 is connected to the sensor 301 via an electrical connection 410. The apparatus 100 of FIG. 2 furthermore comprises a processor device 900, which is in particular in the form of a microprocessor, a DSP or an FPGA. In the example of FIG. 2, the processor device 900 comprises a digital filter device 600 and a control unit 800. The analogue-to-digital converter 500 and the processor device 900 are coupled via an interface 420. The interface 420 is in particular a digital interface, for example a peripheral bus, for example an SPI bus.

The analogue-to-digital converter 500 is configured to convert an analogue signal sequence AF including analogue sensor signals from the sensor 301 into a digital signal sequence DF including digital sensor signals.

The analogue-to-digital converter 500 and the digital filter device 600 connected downstream of the former have the same frequency-synchronized system clock. In particular, the sensor 301 also has the same frequency-synchronized system clock. In the example of FIG. 2, the control unit 800 is configured to clock-synchronously control the sensor 301, the analogue-to-digital converter 500 and the digital filter device 600 via the sequence-synchronized system clock and thereby to synchronize them to one another.

The digital filter device 600 is configured to filter the digital sensor signals of the digital signal sequence DF in a channel-specific manner for providing and storing a respective filtered digital sensor signal for each of the N channels.

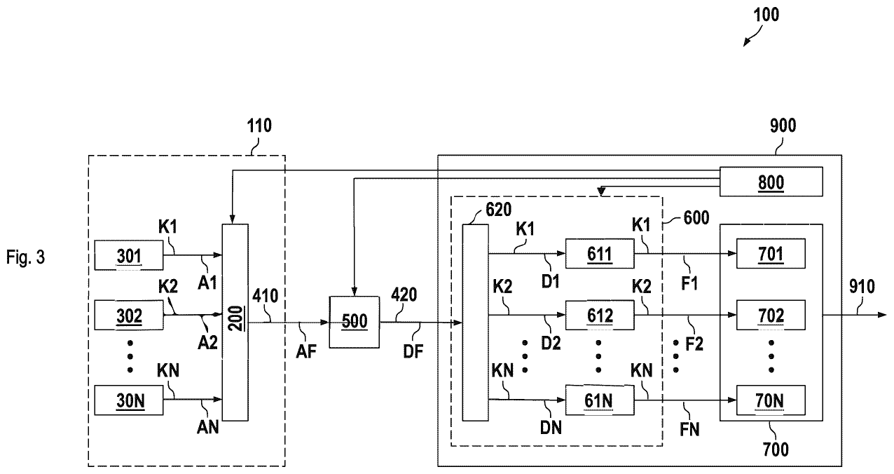

If a plurality of sensors 301 are provided, with N≥2, a multiplexer unit 200 can be used (see for example FIG. 3) or a multi-channel-ready analogue-to-digital converter can be used. An analogue filter (not illustrated) can also be placed between the respective sensor 301 and the analogue-to-digital converter 500.

FIG. 3 shows a schematic illustration of a second embodiment of an apparatus 100. The apparatus 100 is arranged in an optical system 4, 10 of the lithography apparatus 1, for example the illumination optical unit 4 or the projection optical unit 10, and serves to provide sensor data from sensors 301-30N of the optical system 4, 10 of the lithography apparatus 1.

The apparatus 100 in FIG. 3 comprises a vacuum housing 110, for example of the optical system 4. A plurality N of sensors 301-30N and a multiplexer unit 200 are arranged in the vacuum housing 110. The sensors 301-30N comprise for example temperature measurement sensors, such as NTC sensors, photodiodes or capacitors. The sensors 301-30N in particular have in common that they provide an analogue sensor signal A1-AN on the output side.

The multiplexer unit 200 is arranged in FIG. 3 within the vacuum housing 110. In embodiments, the multiplexer unit 200 can also be arranged outside the vacuum housing 110.

The multiplexer unit 200 is configured to receive the analogue sensor signals A1-AN from the plurality N of sensors 301-30N of the optical system 4, 10 via a plurality N of channels K1-KN and to provide on the output side an analogue signal sequence AF including the N multiplexed analogue sensor signals A1-AN via an electrical connection 410. Each sensor 301-30N is assigned a channel K1-KN via which the respective analogue sensor signal A1-AN is supplied to the multiplexer unit 200.

The multiplexer unit 200 can be configured here as an N×1 multiplexer unit 200 which is configured to receive the N analogue sensor signals A1-AN from the N sensors 301-30N of the optical system 4, 10 via the N channels K1-KN and to provide on the output side the analogue signal sequence AF including the N multiplexed analogue sensor signals A1-AN via a single electrical connection 410.

In addition, the apparatus 100 of FIG. 3 comprises an analogue-to-digital converter 500, which is connected to the multiplexer unit 200 via an electrical connection 410. The analogue-to-digital converter 500 is configured to convert the analogue signal sequence AF provided by the multiplexer unit 200 into a digital signal sequence DF including N multiplexed digital sensor signals D1-DN. In this case, the digital sensor signal D1 corresponds to a digital representation of the analogue sensor signal A1. Both, that is to say the digital sensor signal D1 and the analogue sensor signal A1, are assigned to the channel K1. Accordingly, the digital sensor signal D2 corresponds to a digital representation of the analogue sensor signal A2, and both are assigned to the channel K2. The same applies correspondingly for the further digital and analogue signals. Accordingly, the digital signal DN is ultimately a digital representation of the analogue signal AN, and both are assigned to the channel KN.

In FIG. 3, the multiplexer unit 200 is arranged between the sensors 301-30N and the analogue-to-digital converter 500. In embodiments, the multiplexer unit 200 can also be arranged upstream of the sensors 301-30N (not illustrated).

The apparatus 100 of FIG. 3 furthermore comprises a processor device 900, which is in the form of a microprocessor, a DSP or an FPGA, for example. The processor device 900 can also be referred to as processing unit. In the example of FIG. 3, the processor device 900 comprises a digital filter device 600, a storage unit 700, a control unit 800 and an interface 910.

The analogue-to-digital converter 500 is coupled to the digital filter device 600 via an interface 420. The digital filter device 600 is configured to filter the multiplexed digital sensor signals D1-DN of the digital signal sequence DF in a channel-specific manner for the N channels K1-KN for providing and storing a respective filtered digital sensor signal F1-FN for each of the channels K1-KN. For this purpose, the digital filter device 600 of FIG. 3 comprises a plurality N of parallel digital filters 611-61N, with each of the N digital filters 611-61N being assigned exactly one of the channels K1-KN. The digital filter device 600 of FIG. 3 furthermore comprises a demultiplexer unit 620. The demultiplexer unit 620 is arranged between the analogue-to-digital converter 500 and the N digital filters 611-61N. The demultiplexer unit 620 is configured to demultiplex the multiplexed digital sensor signals D1-DN of the digital signal sequence DF in a channel-specific manner for the N channels K1-KN onto the N digital filters 611-61N, that is to say to correctly distribute them in a channel-specific manner. The respective digital filter 611-61N filters the supplied sensor signal D1-DN and provides a filtered digital sensor signal F1-FN on the output side.

The apparatus 100 of FIG. 3 further comprises a storage unit 700. The storage unit 700 is connected downstream of the N digital filters 611-61N and comprises N memory locations 701-70N. Here, each of the N memory locations 701-70N is assigned exactly one of the N channels K1-KN. The respective memory location 701-70N is configured here for storing the respective filtered digital sensor signal F1-FN for the respective one of the N channels K1-KN. In addition, a buffer for the last X sensor signals per channel K1-KN can be present.

The control unit 800 is in particular configured to clock-synchronously control the multiplexer unit 200, the analogue-to-digital converter 500 and the digital filter device 600.

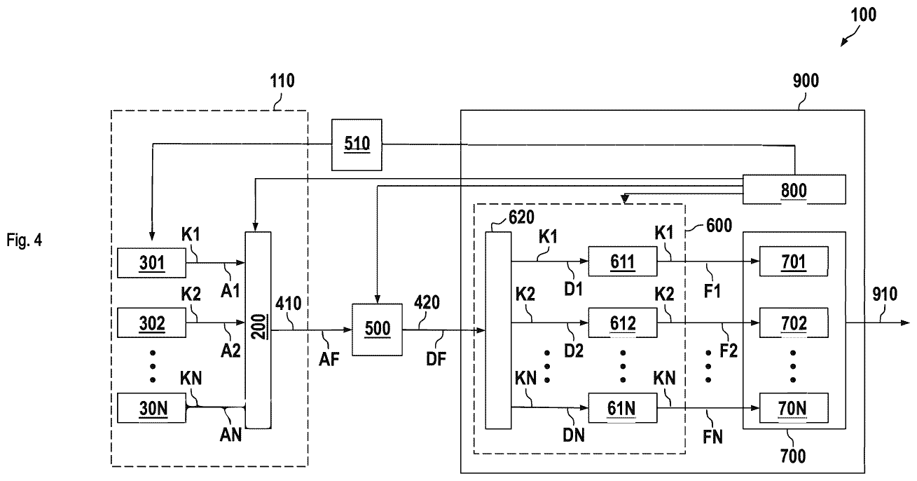

FIG. 4 shows a schematic illustration of a third embodiment of an apparatus 100 for providing sensor data from sensors 301-30N of an optical system 4, 10 of a lithography apparatus 1. The third embodiment of the apparatus 100 according to FIG. 4 comprises all the features of the second embodiment according to FIG. 3. The apparatus 100 of FIG. 4 comprises moreover a digital-to-analogue converter 510. The digital-to-analogue converter 510 is arranged between the control unit 800 and the N sensors 301-30N. The control unit 800 of FIG. 4 is configured here to clock-synchronously control the multiplexer unit 200, the analogue-to-digital converter 500, the digital filter device 600, the storage unit 700 and the N sensors 301-30N via the digital-to-analogue converter 510.

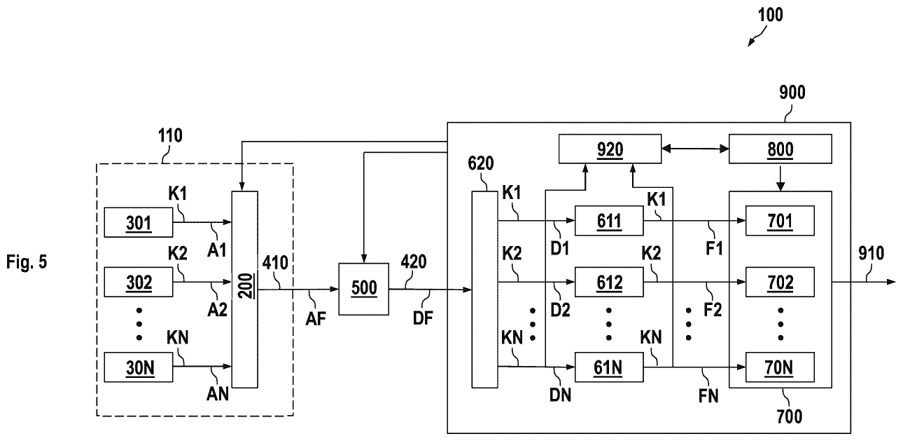

FIG. 5 shows a schematic illustration of a fourth embodiment of an apparatus 100 for providing sensor data from sensors 301-30N of an optical system 4, 10 of a lithography apparatus 1. The apparatus 100 according to FIG. 5 can be based on the apparatus 100 according to FIG. 3 or 4. For drawing reasons, the control lines for the multiplexer unit 200 and the analogue-to-digital converter 500 are shown in FIG. 5 proceeding from the processor device 900. In addition to the apparatus 100 according to FIG. 3 or according to FIG. 4, the apparatus 100 according to FIG. 5 comprises a signal analysis unit 920. The signal analysis unit 920 is configured to analyse the digital sensor signals D1-DN of the digital signal sequence DF and/or the filtered digital sensor signals F1-FN and to adapt in dependence thereon at least one property of the digital filter device 600, in particular the filter coefficients of the digital filter device 600, and/or the sampling frequency of the analogue-to-digital converter 500.

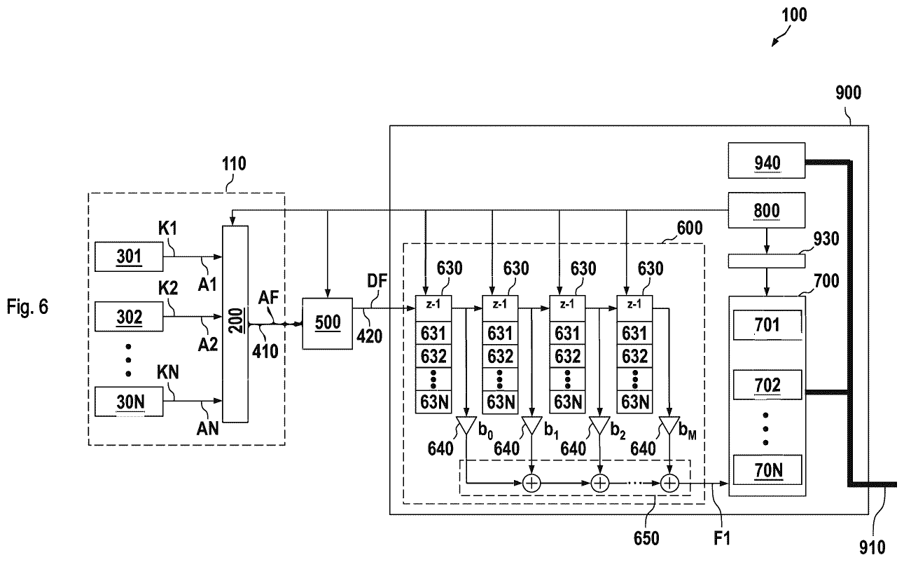

FIG. 6 shows a schematic illustration of a fifth embodiment of an apparatus 100 for providing sensor data from sensors 301-30N of an optical system 4, 10 of a lithography apparatus 1.

The apparatus 100 in FIG. 6 comprises a vacuum housing 110, for example of the optical system 4. A plurality of sensors 301-30N and a multiplexer unit 200 are arranged in the vacuum housing 110. The sensors 301-30N comprise for example temperature measurement sensors, such as NTC sensors, photodiodes or capacitors. The sensors 301-30N in particular have in common that they provide an analogue sensor signal A1-AN on the output side. The multiplexer unit 200 is configured to receive the analogue sensor signals A1-AN from the plurality N of sensors 301-30N of the optical system 4, 10 via a plurality N of channels K1-KN and to provide on the output side an analogue signal sequence AF including the N multiplexed analogue sensor signals A1-AN via an electrical connection 410.

The multiplexer unit 200 can be configured here as an N×1 multiplexer unit 200 which is configured to receive the N analogue sensor signals A1-AN from the N sensors 301-30N of the optical system 4, 10 via the N channels K1-KN and to provide on the output side the analogue signal sequence AF including the N multiplexed analogue sensor signals A1-AN via an electrical connection 410.

In addition, the apparatus 100 of FIG. 6 comprises an analogue-to-digital converter 500, which is connected to the multiplexer unit 200 via the electrical connection 410. The analogue-to-digital converter 500 is configured to convert the analogue signal sequence AF provided by the multiplexer unit 200 into a digital signal sequence DF including N multiplexed digital sensor signals D1-DN.

The apparatus 100 of FIG. 6 furthermore comprises a processor device 900, which is in the form of a microprocessor, a DSP or an FPGA, for example. The processor device 900 can also be referred to as processing unit. The processor device 900 of FIG. 6 comprises a digital filter device 600, a storage unit 700, a control unit 800, an interface or output interface 910, an address encoder 930 and a configuration unit 940 for storing and managing settings or configurations. The interface 910 is coupled in particular to the storage unit 700, the control unit 800 and the configuration unit 940. It is of course possible for the processor device 900 to comprise further components that are coupled to the interface 910. The address encoder 930 is coupled between the control unit 800 and the storage unit 700, with the result that the control unit 800 can access the storage unit 700 via the address encoder 930.

The digital filter device 600 is connected downstream of the analogue-to-digital converter 500 of FIG. 6. The digital filter device 600 is configured to filter the multiplexed digital sensor signals D1-DN of the digital signal sequence DF in a channel-specific manner for the N channels K1-KN for providing and storing a respective filtered digital sensor signal F1-FN for each of the channels K1-KN. For this purpose, the digital filter device 600 of FIG. 6 comprises a plurality M of series-connected delay units 630. The property of the delay of the delay units 630 is illustrated in FIG. 6 by a z⁻¹. The delay units 630 are configured for receiving the digital signal sequence DF including the multiplexed digital sensor signals D1-DN. In this case, the delay units 630 comprise in each case one memory location 631-63N for each of the N channels K1-KN. Consequently, the respective delay unit 630 is configured to store the digital sensor signals D1-DN in a channel-specific manner for the N channels K1-KN in the respectively assigned memory locations 631-63N. Here, each of the N memory locations 631-63N is assigned exactly one of the channels K1-KN. This assignment of the memory locations 631-63N to the channels K1-KN is in particular bijective.

The delay units 630 of FIG. 6 are configured to shift in a channel-specific manner for the N channels K1-KN the memory contents of their memory locations 631-63N in accordance with the system clock into the memory locations 631-63N of the delay unit 630 that is respectively connected downstream.

In addition, a respective multiplier unit 640 is connected downstream of each of the M delay units 630. Each multiplier unit 640 is assigned a specific filter coefficient b1-bM. The delay units 630 are configured here to supply the memory contents of a specific channel of the N channels K1-KN to the M multiplier units 640 in accordance with the system clock. The M multiplier units 640 are configured to multiply the memory contents supplied by the M delay units 630 by the specific filter coefficients b1-bM. An adding unit 650, which can have a plurality of add locations and is connected downstream of the M multiplier units 640, is configured to add up the products of the multiplications provided by the M multiplier units 640 for providing the filtered digital sensor signal F1 of the specific channel K1. In the example of FIG. 6, the channel K1 is the specific channel, and the adding unit 650 consequently provides at this point in time the filtered digital sensor signal F1 of the channel K1 on the output side. This filtered digital sensor signal F1 is then stored in the memory location 701 of the memory unit 700 that is assigned to the channel K1.

As is further shown in FIG. 6, the control unit 800 in FIG. 6 is configured to clock-synchronously control the multiplexer unit 200, the analogue-to-digital converter 500, the delay units 630 and the storage unit 700.

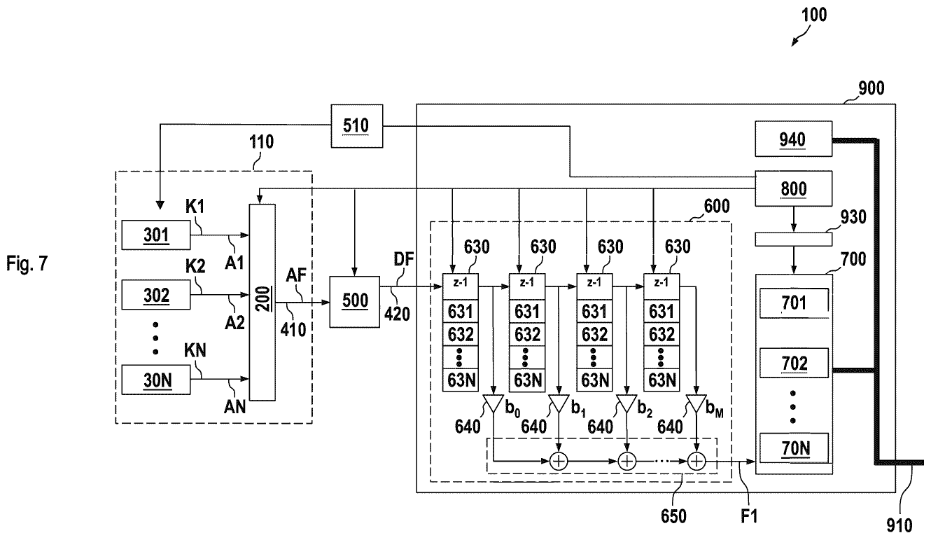

FIG. 7 shows a schematic illustration of a sixth embodiment of an apparatus 100 for providing sensor data from sensors 301-30N of an optical system 4, 10 of a lithography apparatus 1. The sixth embodiment of FIG. 7 is based on the fifth embodiment according to FIG. 6 and comprises all of its features. Moreover, the apparatus 100 of FIG. 7 has in addition a digital-to-analogue converter 510, which is connected between the control unit 800 and the N sensors 301-30N. The control unit 800 is configured here to clock-synchronously control the multiplexer unit 200, the analogue-to-digital converter 500, the delay units 630, the storage unit 700 and the N sensors 301-30N via the digital-to-analogue converter 510.

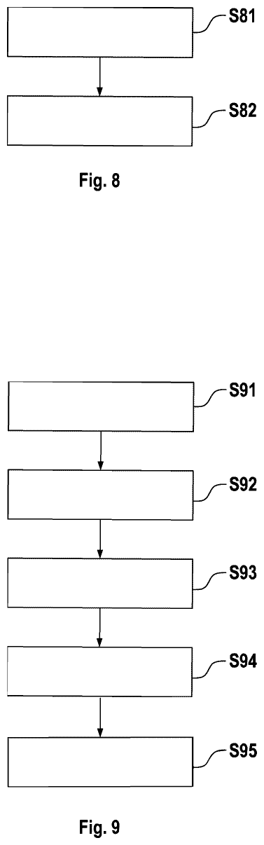

FIG. 8 shows a schematic view of an embodiment of a method for providing sensor data from a number N of sensors 301-30N of an optical system 4, 10 of a lithography apparatus 1. For implementing the method according to FIG. 8, an apparatus 100 according to any of FIGS. 2 to 7 can be used. The method in FIG. 9 comprises the steps S81 and S82:

In step S81, an analogue signal sequence AF, which is provided via a number N of channels K1-KN and includes a number N of analogue sensor signals A1-AN from the number N of sensors 301-30N of the optical system 4, 10, is converted into a digital signal sequence DF including N digital sensor signals D1-DN.

In step S82, the N digital sensor signals D1-DN of the digital signal sequence DF are filtered in a channel-specific manner for providing and storing a respective filtered digital sensor signal F1-FN for each of the N channels K1-KN via a digital filter device 600, which is connected downstream of the analogue-to-digital converter 500, wherein the analogue-to-digital converter 500 and the digital filter device 600 have the same frequency-synchronized system clock.

FIG. 9 shows a schematic view of a further embodiment of a method for providing sensor data from sensors 301-30N of an optical system 4, 10 of a lithography apparatus 1. For implementing the method according to FIG. 9, an apparatus 100 according to any of FIGS. 2 to 7 can be used. The method in FIG. 9 comprises the steps S91-S95:

In step S91, a plurality N of analogue sensor signals A1-AN from a plurality N of sensors 301-30N of the optical system 4, 10 are received via a plurality N of channels K1-KN at a multiplexer unit 200.

In step S92, an analogue signal sequence AF including the N multiplexed analogue sensor signals A1-AN are provided via the multiplexer unit 200.

In step S93, the analogue signal sequence AF is transmitted to an analogue-to-digital converter 500, which is connected to the multiplexer unit 200 via the electrical connection 410.

In step S94, the analogue signal sequence AF is converted into a digital signal sequence DF including N multiplexed digital sensor signals D1-DN via the analogue-to-digital converter 500.

In step S95, the multiplexed digital sensor signals D1-DN of the digital signal sequence DF are filtered in a channel-specific manner for the N channels K1-KN for providing and storing a respective filtered digital sensor signal F1-FN for each of the N channels K1-KN via a digital filter device 600, which is connected downstream of the analogue-to-digital converter 500.

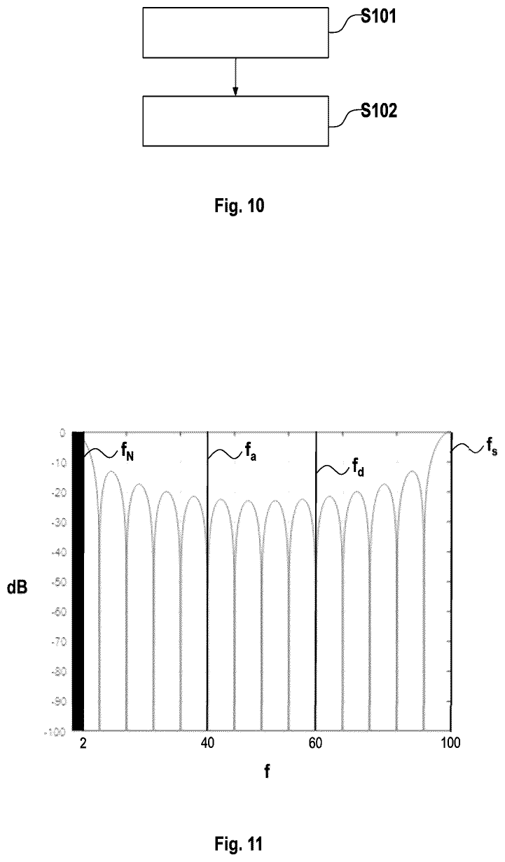

FIG. 10 shows a schematic view of an embodiment of a design method for designing an apparatus 100 for providing sensor data from sensors 301-30N of an optical system 4, 10 of a lithography apparatus 1.

Examples of such an apparatus 100 are explained in particular above with reference to FIGS. 2 to 7. The apparatus 100 comprises at least one analogue-to-digital converter 500 for converting analogue sensor signals A1-AN into digital sensor signals D1-DN and a digital filter device 600, connected downstream of the analogue-to-digital converter 500, for filtering the digital sensor signals D1-DN.

The digital sensor signals D1-DN comprise a used signal frequency of a used signal bandwidth f_{N}, interference signal components, undersampled by the analogue-to-digital converter 500, having an interference frequency f_{d} and interference signal components with at least one specific alias frequency fₐ brought about by the undersampling. In this respect, FIG. 11 shows a schematic diagram for illustrating, by way of example, a sampling frequency of 100 Hz (fₛ=100), an interference frequency of 60 Hz (f_{d}=60 Hz) and an associated alias frequency of 40 Hz (fₐ=40 Hz). The used signal bandwidth f_{N} in the example of FIG. 11 is 2 Hz (f_{N}=2 Hz).

The method according to FIG. 10 comprises the steps S101 and S102:

In step S101, the sampling frequency f_{f} of the analogue-to-digital converter 500 is selected such that the interference frequency fₐ and the alias frequency fₐ lie outside the used signal bandwidth f_{N} and the sampling frequency fₛ is not a submultiple of the interference frequency f_{d}.

In step S102, the sampling frequency fₛ of the analogue-to-digital converter 500 and the filter order M of the digital filter device 600 are selected such that the digital filter device 600 allows the signal components within the used signal bandwidth f_{N} to pass and suppresses the aliasing frequencies fₐ of the undersampled interference signal components.

For the example of a moving average filter as digital filter device 600, the sampling frequency of the analogue-to-digital converter 500 and the filter order can be selected such that the quotient of the sampling frequency fₛ and the filter order corresponds to a submultiple of the alias frequency fₐ and is greater than the used signal bandwidth f_{N}.

The digital filter device 600 is in particular in the form of a notch filter. An exemplary frequency profile for such a notch filter 600 is also illustrated in FIG. 11. The frequency profile of the notch filter 600 according to FIG. 11 illustrates that the alias frequency fₐ at 40 Hz is filtered out, whereas the used signal with fₙ=2 Hz is not filtered out.

The present design method according to FIG. 11 is used in particular for undersampled interference frequencies f_{d}. The interference frequency f_{d} or the interference frequencies and the alias frequency fₐ or alias frequencies are determined and therefore known a priori. The present design method accordingly is used in particular when the sampling rate of the analogue-to-digital converter 500 is too low to be able to sample a specific interference frequency f_{d} according to the Nyquist-Shannon sampling theorem, in particular either due to a very precise but slow analogue-to-digital converter 500 and/or due to multiplexing of a plurality of signals from multiple channels K1-KN that are to be processed in parallel. In the case of such undersampling of the interference frequency f_{d}, aliasing effects occur, as a result of which the interference frequency f_{d} occurs mirrored in a low frequency band. This is referred to, as mentioned above, as mirrored interference frequency or alias frequency fₐ.

According to the present design method, the sampling frequency f_{S} of the analogue-to-digital converter 500 and the filter order M of the digital filter device 600 are selected such that the following three conditions I, II and III are met:

### Condition I

The sampling frequency f_{S} of the analogue-to-digital converter 500 is selected such that the at least one alias frequency fₐ lies outside the used signal bandwidth f_{N} of the digital sensor signals D1-DN. In addition, the sampling frequency f_{S} of the analogue-to-digital converter 500 is selected such that it is greater than twice the used signal bandwidth f_{N}.

### Condition II

The sampling frequency f_{S} of the analogue-to-digital converter 500 is selected such that the sampling frequency f_{S} is not a submultiple of the interference frequency f_{d}.

### Condition III:

The digital filter device 600 has a low-pass behaviour which allows signal components within the used signal bandwidth f_{N} to pass and suppresses the aliasing frequencies fₐ of the undersampled interference signal components.

For the example of the moving average filter as digital filter device 600, the condition III can be formulated using the conditions IIIa and IIIb:

### Condition IIIa

The sampling frequency f_{S} of the analogue-to-digital converter 500 and the filter order m of the digital filter device 600 are selected such that the quotient of the sampling frequency f_{S} and the filter order M corresponds to a submultiple of the alias frequency fₐ.

### Condition IIIb

The sampling frequency f_{S} of the analogue-to-digital converter 500 and the filter order M of the digital filter device 600 are selected such that the quotient of the sampling frequency f_{S} and the filter order m is greater than the used signal bandwidth f_{N}.

The filter order m of the digital filter device 600 corresponds in particular to the plurality M of series-connected delay units 630 of the digital filter device (in this respect, see FIG. 6).

The apparatus 100 designed using the present design method, which apparatus 100 comprises an analogue-to-digital converter 500 and a digital filter device 600, is capable of filtering alias frequencies fₐ of the undersampled known interference frequencies f_{d} without influencing the used signal bandwidth f_{N} of the used signal.

Based on the above conditions I to III, the filter order M of the digital filter device 600 is selected at a sampling frequency fₛ of 100 Hz, a used signal of 2 Hz, an interference frequency f_{d} of 60 Hz and an alias frequency fₐ at 40 Hz as follows:
1. A submultiple of the mirrored interference frequency fₐ of 40 Hz is 10.
2. For the divisor 10: f_{S}/M=10→M=10. The divisor 10 and the resulting filter order M=10 meet all the conditions I to III (IIIa and IIIb). Consequently, the filter order M=10 is admissible for the present example.

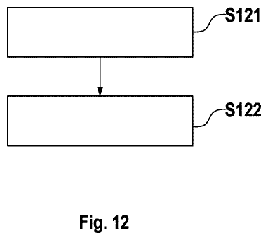

FIG. 12 shows a schematic view of an embodiment of a method for operating an apparatus 100 for providing sensor data from sensors 301-30N of an optical system 4, 10 of a lithography apparatus 1.

The apparatus 100, which is operated in accordance with FIG. 12, is in particular the apparatus 100 according to one of FIGS. 3 to 5. The method according to FIG. 12 comprises controlling the analogue-to-digital converter 500 and the digital filter device 600 and includes the steps S121 and S122.

In step S121, the analogue-to-digital converter 500 is controlled such that it converts from each of the N channels K1-KN in turn a successive series of sensor signal values of the analogue sensor signals A1-AN into digital sensor signals D1-DN.

In step S122, the digital filter device 600 is subsequently controlled such that it filters the digital sensor signals D1-DN provided by the analogue-to-digital converter 500.

In particular, the digital filter device 600 averages the raw values of the digital sensor signals D1-DN of the respective channel K1-KN over the time period of an integer known period of the interference signal component for providing the digital sensor signals F1-FN. Narrowband known interference frequencies fₐ can be filtered out by way of this averaging. In this way, the alias frequencies of the interference frequencies occurring due to the undersampling are filtered out.

Although the present disclosure has been described with reference to exemplary embodiments, it is modifiable in various ways.

### LIST OF REFERENCE SIGNS

1 Projection exposure apparatus
2 Illumination system
3 Light source
4 Illumination optical unit
Object field
6 Object plane
7 Reticle
8 Reticle holder
9 Reticle displacement drive
Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Apparatus
110 Vacuum housing
200 Multiplexer unit
301-30N Sensor
410 Electrical connection
420 Interface
500 Analogue-to-digital converter
510 Digital-to-analogue converter
600 Digital filter device
611-61N Digital filter
620 Demultiplexer unit
630 Delay unit
631-63N Memory location
640 Multiplier unit
650 Adding unit
700 Storage unit
701-70N Memory location
800 Control unit
900 Processor device
910 Interface
920 Signal analysis unit
930 Address encoder
940 Configuration unit
AF Analogue signal sequence
A1-AN Analogue sensor signal
b₁-b_{M} Filter coefficient
K1-KN Channel
D1-DN Digital sensor signal
DF Digital signal sequence
f Frequency
fₐ Alias frequency
f_{d} Interference frequency
fₛ Sampling frequency
f_{N} Used signal bandwidth
F1-FN Filtered digital sensor signal
M1 Mirror
M2 Mirror
M3 Mirror
M4 Mirror
M5 Mirror
M6 Mirror
S81-S82 Method step
S91-S95 Method step
S101-S102 Method step
S121-S122 Method step

What is claimed is:

1. An apparatus, comprising:
a multiplexer unit;
an analogue-to-digital converter unit; and
a digital filter device,
wherein:
the multiplexer unit is configured to: i) receive a number N of analogue sensor signals from N sensors of an optical system via N channels, N being at least one; and ii) provide to the analogue-to-digital converter unit an analogue signal sequence comprising N multiplexed analogue sensor signals;
the analogue-to-digital converter is configured to convert the analogue signal sequence into a digital signal sequence comprising N digital sensor signals;
the analogue-to-digital converter is configured to provide the N digital sensor signals to the digital filter device;
the digital filter device is configured to filter the N digital sensor signals in a channel-specific manner to provide and store a respective filtered digital sensor signal for each of the N channels; and
the analogue-to-digital converter and the digital filter device have the same frequency-synchronized system clock.

2. The apparatus of claim 1, further comprising: a control unit configured to clock-synchronously control the analogue-to-digital converter and the digital filter device via the frequency-synchronized system clock.

3. The apparatus of claim 1, wherein the digital filter device comprises:
a demultiplexer unit; and
N digital filters,
wherein:
the demultiplexer unit is connected between the analogue-to-digital converter and the N digital filters;
the demultiplexer is configured to demultiplex the N digital sensor signals in a channel-specific manner;
for each of the N channels, the demultiplexer provides the corresponding demultiplexed digital sensor signal to exactly one of the N digital filters.

4. The apparatus of claim 3, further comprising a storage unit comprising N memory locations, wherein each of the N memory locations is assigned to exactly one of the N channels so that each of the N memory locations is configured to store the respective filtered digital sensor signal for the respective one of the N channels.

5. The apparatus of claim 2, further comprising a digital-to-analogue converter connected between the control unit and the N sensors, wherein the control unit is configured to clock-synchronously control the multiplexer unit, the analogue-to-digital converter, the digital filter device, the storage unit, and/or the N sensors via the digital-to-analogue converter (510).

6. The apparatus of claim 1, wherein:
the digital filter device comprises a plurality M of series-connected delay units configured to receive the digital signal sequence;
each delay unit comprises one memory location for each of the N channels;
each of the N memory locations is assigned to exactly one of the N channels; and
the delay units are configured to shift in a channel-specific manner for the N channels the memory contents of their memory locations in accordance with the system clock into the memory locations of the delay unit that is respectively connected downstream.

7. The apparatus of claim 6, further comprising an adding unit and a storage unit, wherein:
a respective multiplier unit is connected downstream of each of the M delay units;
each multiplier unit is assigned a specific filter coefficient;
the delay units are configured to supply the memory contents of a specific channel of the N channels to the M multiplier units in accordance with the system clock;
the M multiplier units are configured to multiply the memory contents supplied by the M delay units by the specific filter coefficients;
the adding unit is connected downstream of the M multiplier units;
the adding unit is configured to add up products of the multiplications provided by the M multiplier units to provide the filtered digital sensor signal of the specific channel;
the storage unit is connected downstream of the adding unit;
the storage unit comprises N memory locations;
each of the N memory locations is assigned to exactly one of the N channels; and
the respective memory location is configured for storing the respective filtered digital sensor signal for the respective one of the N channels.

8. The apparatus of claim 7, wherein the control unit is configured to clock-synchronously control the multiplexer unit, the analogue-to-digital converter, the delay units and the storage unit via the frequency-synchronized system clock.

9. The apparatus of claim 8, further comprising a digital-to-analogue converter connected between the control unit and the N sensors, wherein the control unit is configured to clock-synchronously control the multiplexer unit, the analogue-to-digital converter, the delay units, the storage unit and the N sensors via the digital-to-analogue converter via the frequency-synchronized system clock.

10. The apparatus of claim 8, comprising a processor device which comprises the digital filter device, the storage unit and the control unit.

11. The apparatus of claim 10, wherein the processor device further comprises a signal analysis unit configured to: i) analyse the digital sensor signals and/or the filtered digital sensor signals; and ii) adapt in dependence thereon at least one property of the digital filter device and/or a sampling frequency of the analogue-to-digital converter.

12. The apparatus of claim 1, further comprising a vacuum housing which houses the N sensors and the multiplexer unit, wherein the analogue-to-digital converter and the digital filter device are outside the vacuum housing.

13. The apparatus of claim 1, wherein the apparatus does not comprises an analogue filter.

14. An optical system, comprising:
an apparatus according to claim 1,
wherein the apparatus is a lithography apparatus.

15. A lithography apparatus, comprising:
an optical system which comprises the apparatus of claim 1.

16. A method for providing sensor data from a number N, with N≥1, of sensors of an optical system, the method comprising:
converting an analogue signal sequence, which is provided via N channels and comprises N analogue sensor signals from the N sensors, into a digital signal sequence comprising N digital sensor signals; and
filtering the N digital sensor signals in a channel-specific manner for providing and storing a respective filtered digital sensor signal for each of the N channels via a digital filter device connected downstream of the analogue-to-digital converter, the analogue-to-digital converter and the digital filter device having the same frequency-synchronized system clock,
wherein N analogue sensor signals from the N sensors are received via N channels via a multiplexer unit and an analogue signal sequence comprising N multiplexed analogue sensor signals is provided to the analogue-to-digital converter.

17. A design method for designing an apparatus comprising an analogue-to-digital converter for converting analogue sensor signals into digital sensor signals and a digital filter device, connected downstream of the analogue-to-digital converter, for filtering the digital sensor signals, which include a used signal component with used signal frequencies of a used signal bandwidth and an interference signal component with at least one determinable alias frequency of a known interference frequency undersampled by the analogue-to-digital converter in the analogue sensor signal, the design method comprising:
a) selecting the sampling frequency of the analogue-to-digital converter so that the at least one alias frequency lies outside the used signal bandwidth and the sampling frequency is not a submultiple of the interference frequency; and
b) selecting the sampling frequency of the analogue-to-digital converter and the filter order of the digital filter device with low-pass behaviour in such a way that the digital filter device allows the signal components within the used signal bandwidth to pass and suppresses the at least one aliasing frequency of the undersampled interference signal components.

18. The design method of claim 17, wherein the digital filter device comprises a notch filter.

19. The design method of claim 17, wherein the digital filter device comprises a moving average filter in an FIR filter structure.

20. The design method of claim 17, wherein a plurality of digital filter devices are connected in series to improve the signal-to-noise ratio of the filtered digital sensor signals.

21. An apparatus, comprising:
an analogue-to-digital converter configured to convert analogue sensor signals into digital sensor signals;
a digital filter device connected downstream of the analogue-to-digital converter, the digital filter device having low-pass behaviour to filtering the digital sensor signals which include a used signal component with used signal frequencies of a used signal bandwidth and an interference signal component with at least one determinable alias frequency of a known interference frequency undersampled by the analogue-to-digital converter in the analogue sensor signal,
wherein the sampling frequency of the analogue-to-digital converter and the filter order of the digital filter device are configured so that the at least one alias frequency lies outside the used signal bandwidth and the sampling frequency is not a submultiple of the interference frequency and so that the digital filter device allows the signal components within the used signal bandwidth to pass and suppresses the at least one alias frequency of the undersampled interference signal components.
